(19) United States
(12) Patent Application Publication
(10) Pub. No.: US 2012/0099255 A1
(43) Pub. Date: Apr. 26, 2012

(54) REFRIGERATOR

(75) Inventors: Su-Won Lee, Gyeongsangnam-do (KR); Seong-Taik Kim, Gyeongsangnam-do (KR); Sung-Eun Kim, Gyeongsangnam-do (KR)

(73) Assignee: LG ELECTRONICS INC., Seoul (KR)

(21) Appl. No.: 13/265,557

(22) PCT Filed: Sep. 3, 2009
(86) PCT No.: PCT/KR09/04963

§ 371 Date: Oct. 21, 2011

(30) Foreign Application Priority Data
May 12, 2009 (KR) 10-2009-0041058

(51) Int. Cl. H05K 7/00; F25D 25/00

(52) U.S. Cl. 361/679.01; 312/404

(57) ABSTRACT

The present invention relates to a refrigerator.

With the refrigerator according to the embodiment of the present invention, the personal receiving space of each of the members who use the refrigerator is provided, making it possible to improve the satisfaction for the product.

### TECHNICAL FIELD

The present invention relates to a refrigerator.

### BACKGROUND ART

Generally, a refrigerator, which is an apparatus that intends to store foods at a low temperature, is constituted to keep foods in a frozen or refrigerated state according to the sort of foods to be preserved.

The inside of the refrigerator is cooled by cooling air that is continuously supplied, wherein the cooling air is continuously generated by the heat exchanging operation of coolant by a cold cycle passing through the processes of compression-condensation-expansion-evaporation. And, the cooling air supplied into the inside of the refrigerator is transferred evenly to the inside of the refrigerator by convection so that the foods inside the refrigerator can be stored at a desired temperature.

Generally, the main body of the refrigerator has a hexahedral shape whose front surface is opened, wherein a refrigerating chamber and a freezing chamber are included in the inside of the main body. And, a refrigerating chamber door and a freezing chamber door that selectively open and close opening are provided at the front surface of the main body.

And, a plurality of drawers, shelves, receiving boxes, etc. that allow various foods to be preserved in an optimal state are provided in the internal storage space of the refrigerator. Further, a plurality of baskets are provided at the rear surfaces of the doors. The internal storage space of the refrigerator is partitioned by the shelves, the receiving boxes, baskets, etc. so that suitable foods can be stored therein.

Generally, one refrigerator is provided in one home. Therefore, a plurality of members share one refrigerator. With the recent trend to respect the personal tastes of members and the personalities thereof, the trend has been more personalized. However, the refrigerator has been shared by the plurality of members, having a problem that the personalities of each user cannot be reflected on the refrigerator. Moreover, all of the storage space provided in the refrigerator are also shared, having a problem that food receiving space that can be used for personal purpose is not independently provided.

Meanwhile, in connection with the foods stored in the refrigerator, there are often cases where a message should be left to another user who uses the refrigerator. For example, there may be cases where a message should be left, the message instructing him or her to drink milk soon since the expiration date thereof is almost close or not to have Kimchi since it seems to be spoiled, etc. In this case, the user who wishes to leave the message should separately call another user or leave a message thereto. In this case, there is no problem when the message is smoothly transferred, but the message may not be smoothly transferred due to specific reasons.

Moreover, since radio frequency identification (RFID) technology is recently applied in managing the food information of the refrigerator, the food information stored in the refrigerator is automatically recognized and the food information is stored and managed in a memory, making it possible to provide information on the sort, state, expiration date, etc. of food, to the user. Therefore, the user can mitigate inconvenience that is caused in separately confirming the sort, state, expiration date, etc. of the food to be stored.

### DISCLOSURE

### Technical Problem

The present invention proposes to overcome the above problems. It is an object of the present invention to provide a refrigerator that provides a personal receiving space.

Moreover, it is an object of the present invention to provide a refrigerator that can change the size of the personal receiving space according to a user's intention.

Further, it is an object of the present invention to provide a refrigerator that can decorate the personal receiving space in accordance with the user's tastes.

In addition, it is an object of the present invention to provide a refrigerator that can be used as the device of communication between users who use the refrigerator.

Moreover, it is an object of the present invention to provide a refrigerator that uses RFID technology so that the communication can be smoothly made.

### Technical Solution

In order to achieve the above objects, according to one embodiment of the present invention, there is provided a refrigerator including: a main body that has a refrigerating chamber and a freezing chamber that store foods at low temperature; a refrigerating chamber door and a freezing chamber door that selectively open and close the refrigerating chamber and the freezing chamber; a personal chamber that is provided between the refrigerating chamber and the freezing chamber; a drawer that is slidably and drawably provided in the personal chamber; at least one partition that partitions a receiving space inside the drawer; and a display unit that is provided on the front surface of the drawer to display partition bars on positions corresponding to positions of the partitions.

According to another embodiment of the present invention, there is provided a refrigerator including: a main body that has a refrigerating chamber and a freezing chamber that store foods at low temperature; a refrigerating chamber door and a freezing chamber door that selectively open and close the refrigerating chamber and the freezing chamber; a plurality of personal chambers that are provided between the refrigerating chamber and the freezing chamber; drawers that are slidably and drawably provided in the respective personal chambers; a display unit that is provided on a front surface of the respective drawers to display user information of the corresponding personal chamber; and fixing devices that are provided in the drawers to selectively fix the drawers to the main body according to user who intends to open the drawers.

### Advantageous Effects

With the refrigerator according to the embodiment of the present invention, the personal receiving space of each of the members who use the refrigerator is provided, making it possible to improve the satisfaction for the product.

Moreover, the area of the personal receiving space can be easily changed, making it possible to conveniently utilize the personal receiving space according to the use purpose.

Further, the personal receiving space can be decorated according to his or her tastes, making it possible to maximize the satisfaction.

In addition, the communication between one user who uses the refrigerator and the other user who uses the personal receiving space can be made through the refrigerator, making it possible to maximize the utilization of the product.

Moreover, in the communication, the relevant food information is also provided using the RFID technique, making it possible to improve use convenience.

### DESCRIPTION OF DRAWINGS

FIG. 1 is a perspective view showing an external appearance of a refrigerator according to a first embodiment of the present invention;

FIG. 2 is an exploded perspective view showing the constitution of the personal chamber drawer of FIG. 1;

FIG. 3 is a partial enlarged view of guide grooves to which the partitions of FIG. 2 are coupled;

FIG. 4 is a diagram showing a screen onto which the user information of the personal chamber of FIG. 1 is input;

FIG. 5 is a diagram showing a screen on which a message is left to the user of the personal chamber of FIG. 1;

FIG. 6 is a diagram showing the display unit of the personal chamber drawer of FIG. 1; and

FIG. 7 is a diagram showing an external appearance of a refrigerator according to a second embodiment of the present invention.

### MODE FOR INVENTION

Hereinafter, the exemplary embodiments for implementing the idea of the present invention will be described in detail with reference to the accompanying drawings.

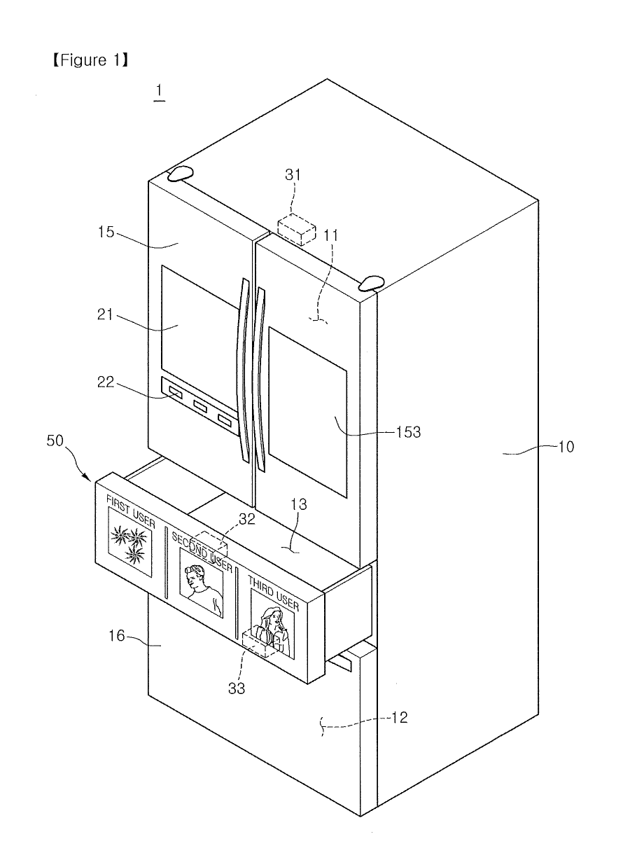

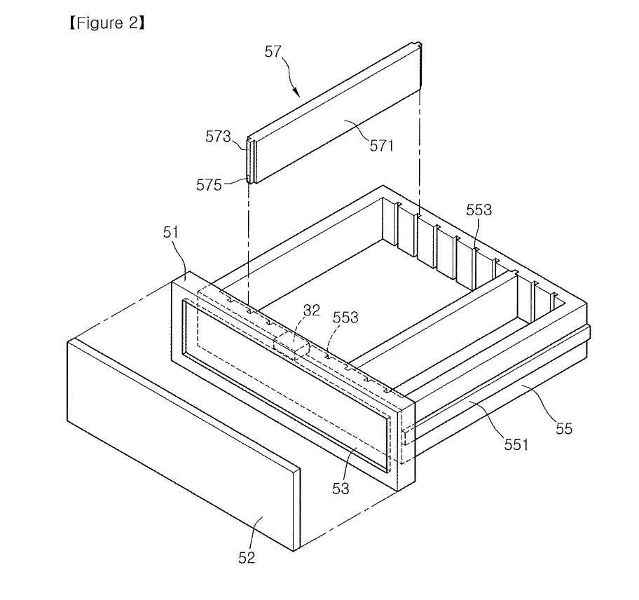

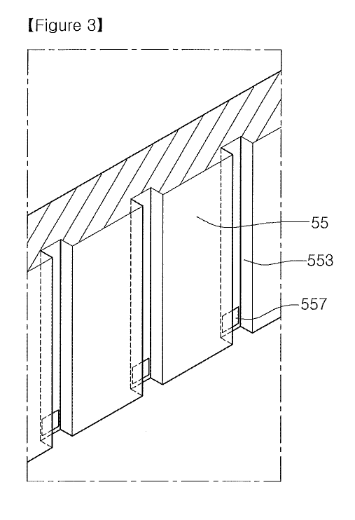

FIG. 1 is a perspective view showing an external appearance of a refrigerator according to a first embodiment of the present invention, FIG. 2 is an exploded perspective view showing the constitution of the personal chamber drawer of FIG. 1, and FIG. 3 is a partial enlarged view of guide grooves to which the partitions of FIG. 2 are coupled.

Referring to FIGS. 1 to 3, the refrigerator 1 according to the first embodiment of the present invention includes a main body 10 that forms an external appearance, a refrigerating chamber 11 that is provided in the upper side of the storage space formed inside the main body 10 and stores food in a refrigerated state, a freezing chamber 12 that is provided in the lower side of the storage space and stores foods in a frozen state, and a personal chamber 13 that is provided in the space between the refrigerating chamber 11 and the freezing chamber 12. The refrigerating chamber 11 and the personal chamber 13, and the personal chamber 13 and the freezing chamber 12 are partitioned by a barrier filled with heat insulating material, being provided as an independent space.

Herein, the location of the refrigerator chamber, the freezing chamber, and the personal chamber is nothing but one example, but they may be located in various shapes, such as a top mount type where the freezing chamber is positioned in the upper side, a side by side type where the freezing chamber and the refrigerating chamber are located side by side, etc. Such a change is within the scope of the idea of the present invention.

The refrigerating chamber 11 is opened and closed selectively by refrigerating chamber doors 15 that are provided rotatably on both sides of the main body 10, and the freezing chamber 12 is opened and closed selectively by a freezing chamber door 16 that is provided rotatably in front and rear direction to the main body 10. And, the personal chamber 13 is opened and closed selectively by a personal chamber door 51 provided in a drawer 50 to be described later.

The refrigerating chamber door 15 includes an input device 21 that can confirm the operation situation of the refrigerator 1 or input commands on the operation of the refrigerator 1. Also, the user can leave a message to a user of the personal chamber 13 using the input device 21.

The input device 21 may be provided in a touch screen scheme. The technique to provide the input device 21 in a touch screen scheme in the refrigerator has been disclosed in detail in Korean Patent Laid-Open Publication Nos. 10-2008-0004307, 10-2002-0055516, etc. filed by the present applicant so that the detailed explanation thereof will be omitted herein. For another example, the input device 21 may be provided to include a plurality of buttons and a predetermined display device on which contents that is changed by manipulating the buttons is displayed.

A communication port 22 that can transmit and receive data with an external memory device is provided on one side of the input device 21. A universal serial bus (USB) storage device, a digital camera, etc. may be connected to the communication port 22. An image file can be stored in the external memory device, and a user can use images stored in the external memory device by manipulating the input device 21. The technique to provide the communication port capable of transmitting and receiving data with the external memory device in the refrigerator has been disclosed in detail in Korean Patent Laid-Open Publication Nos. 10-2006-0120800, 10-2008-0035102, etc. filed by the present applicant so that the detailed explanation thereof will be omitted herein. Furthermore, in the present embodiment, the USB storage device will be used as the external memory device by way of example.

Meanwhile, a home bar 153 that a user can take out the food stored inside the refrigerating chamber 11 without opening the refrigerating chamber door 15 may further be included in the refrigerating chamber door 15.

Moreover, a radio frequency identification (RFID) reader that comprehends the food information that comes out and in the respective storage spaces may be provided in the main body 10 or the doors 15, 16 and 51. In other words, three RFID readers may be provided: a refrigerating chamber RFID reader 31, a freezing chamber RFID reader 32, a personal chamber RFID reader 32, etc. The RFID readers 31, 32, and 33 are communicated with RFID tags attached to the food or dishes to read out the corresponding food information. And, the information comprehended in the RFID reader is stored in the memory (not shown) of the refrigerator 1. The RFID readers are provided in the respective storage spaces as described above, making it possible to store in the memory what food is stored in a certain storage space.

The personal chamber 13 may be used in the case where a plurality of users who use the refrigerator 1 wish to have their own space for preserving food. The personal chamber 13 is provided as an independent space from the refrigerating chamber 11 and the freezing chamber 12, wherein the drawer 50 that is slidable in front and rear direction is provided.

At this time, the temperature of the personal chamber 13 can be controlled by the input device 21.

More specifically, the personal chamber 13 is communicated with the refrigerating chamber 11 and the freezing chamber 12, wherein a predetermined damper is provided in a passage that is communicated with the respective storage chambers, making it possible to control the amount of cooling air that comes in and out the personal chamber 13. And, the input device 21 can set the proper temperature of the personal chamber 13 according to use of the personal chamber 13 and a controller (not shown) of the refrigerator 1 can control the amount of cooling air flowed into the personal chamber 13 by controlling the damper. Therefore, the personal chamber 13 can not only preserve general food in a refrigerated state or in a frozen state but also preserve food requiring a specific temperature bandwidth in order to maintain an optimal state of vegetables or wines, etc.

More specifically, the drawer 50 includes a personal chamber door 51 that opens and closes opening of the personal chamber 13, a display unit 53 that is mounted to the personal chamber door 51, a door cover 52 that is coupled to the front surface of the personal chamber door 51 and is formed of transparent or translucent material so that ah image displayed on the display unit 53 can be transmitted, and a container 55 that is coupled to the rear surface of the personal chamber door 51 and provides a space capable of receiving food.

The personal chamber door 51 is formed in a shape corresponding to the shape of the entrance of the personal chamber 13, wherein its front surface may be recessed at a predetermined depth so that the display unit 53 can be mounted thereto. The display unit 53 has a display panel such as a LCD or a PDP, etc. The display panel receives signal from the controller, making it possible to represent the information on the user who uses the personal chamber 13. And, the personal chamber RFID reader 32 may be provided on the upper side of the personal chamber door 51.

The door cover 52 may be formed of tempered glass, etc. made of transparent material so that the user can recognize the information displayed on the display unit 53.

Meanwhile, the container 55 is coupled to the rear surface of the personal chamber door 51. The container 55 may be provided in a rectangular-shaped box shape whose upper surface is opened so that the user can receive food. Slide rails 551 are projected on both sides of the container 55, wherein the slide rails 551 are extended in front and rear direction. And, slide guides (not shown) corresponding to the slide rails 551 are formed in an inner case that forms the personal chamber 13. The slide rails 551 are seated on the slide guides to be slid so that the drawer 50 can be slidingly drawn in and out in front and rear direction. In a state where the drawer 50 is drawn out, the user can receive food in the drawer 50, and in a state where the drawer 50 is drawn in, the personal chamber door 51 opens and closes the personal chamber 13.

Moreover, at least one partition 57 that partitions the internal space of the container 55 may be provided in the container 55. The partition 57 is inserted into the container 55 to partition the storage space side by side. In other words, the inside of the container 55 is partitioned into one more spaces than the number of the partitions 57.

More specifically, the partition 57 is formed in a plate shape having the length corresponding to the horizontal width of the container 55, wherein guide projections 573 are projected on a front end portion and a rear end portion, respectively. The guide projections 573 are inserted into guide grooves 553 to be described later to fix the partitions 57 to the container 55. And, a metal plate 575 is formed on the lower end portion of the guide projections 573 so that a position that the partition 57 is inserted can be confirmed.

A pair of guide grooves 553 into which the partitions 57 are inserted is formed at a front wall and a rear wall of the container 55, wherein the pair of guide grooves 553 are formed to face each other. The guide groove 553 is vertically extended so that the partition 57 can be inserted from the upper side, wherein a groove formed at the front wall and a groove formed at the rear wall are formed on the same position so that the partition 57 can be inserted parallelley into the side wall of the container 55. Further, the guide groove 553 is formed in a size corresponding to the guide projection 573 so that the partition 57 can be firmly fixed.

A plurality of guide grooves 553 are formed in right and left direction to the container 55. Therefore, the user can divide and use the container 55 in his or her desired size by inserting the partition 57 into his or her desired position.

Electrodes 557 that sense whether the partitions 57 are inserted are provided at least one of the pair of guide grooves 553. Further, the electrodes 557 are provided in all of the pair of guide grooves 553. In other words, the electrodes 557 may be provided to correspond to the number of guide grooves 553 arranged in right and left direction. And, the electrodes 557 are connected to the controller so as to determine the positions where the partitions 57 are inserted. In the present embodiment, the metal plate 575 is provided on the guide projection 573 formed on the front end of the partition 57 and the electrode 557 is provided on one of the guide grooves 553, the one being formed on the front surface of the container 55, by way of example.

Moreover, when the partitions 57 are completely inserted into the guide grooves 553, the electrodes 557 are provided in the positions to contact the metal plates 575. At this time, the controller can sense the change such as current generated when the metal plate 575 contacts the electrode 557, etc. Therefore, the controller can sense whether the partitions 57 are inserted.

Further, since the electrode 557 is provided in each of the pair of guide grooves, the controller can determine the position where the partition 57 is inserted. More specifically, the number of and the positions of the guide grooves 553 formed in the container 55 can be stored in the memory of the refrigerator 1 connected to the controller. The controller may determine the positions where the partitions 57 are inserted by comparing the positions of the electrodes recognizing that the partitions 57 are inserted with the information stored in the memory. For example, when nine pairs of guide grooves 553 are provided, total nine electrodes 557 may be provided, each for the pair of guide grooves 553. The position information in which the nine pair of guide grooves 553 are formed is memorized in the memory. At this time, if the contact with the metal plate is sensed in the second electrode and the seventh electrode, the controller may determine that two partitions 57 are inserted, one being inserted into the second guide groove and the other being inserted into the seventh guide groove.

Herein, the guide groove 553, a part to which the partition 57 is inserted, may be referred to as a coupling part. The coupling part may be provided in a projection shape and in this case, the partition 57 may be formed with a groove corresponding thereto.

As described above, if the position information of the partitions 57 is determined, it can be understood how the container 55 is partitioned and this information may be displayed on the display unit 53. The detailed description related thereto will be described later. Further, in the present embodiment, a case where two partitions 57 are provided will be described by way of example.

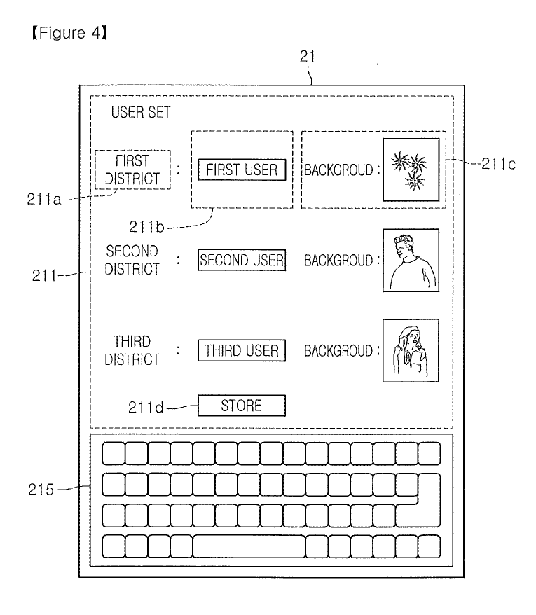

FIG. 4 is a diagram showing a screen onto which the user information of the personal chamber of FIG. 1 is input.

Referring to FIG. 4, a user set screen 211 onto which the user information of the personal chamber 13 is input and a character input screen 215 onto which characters and symbols, etc. are input may be displayed on the input device 21. The user set screen 211 and the character input screen 215 are provided in a touch screen scheme, respectively, so that if the user touches the input device 21, the commands or characters, etc. corresponding to the touched portions may be input into the controller.

Moreover, the user set screen 211 may be set to be displayed on the input device 21 when a predetermined menu provided in the input device 21 is selected or may be set to be automatically displayed on the input device 21 when there is a change in the positions or the number of the partitions 57.

The controller automatically sets the user set screen 211 so that the same number of user information as the number of space partitioned by the partitions 57 can be set. For example, when the container 55 is partitioned into three spaces, the controller sets the screen so that three kinds of user information can be set.

And, the user set screen 211 includes a district display unit 211a that displays the spaces partitioned by the partitions 57, a name input unit 211b that input names such as names and nicknames, etc. of the user who will use the corresponding district, and an image selecting unit 211c that selects the image to be displayed on the corresponding district.

In the present embodiment, two partitions 57 are provided so that the container 55 is partitioned into three spaces, wherein the three spaces are named as a first district, a second district, and a third district from the left, respectively, to be displayed sequentially on the district display unit 211a.

And, the name input unit 211b that inputs the name of the user who uses the corresponding district is displayed on one side of the respective district names. If the user touches the name input unit 211b, the controller can activate the character input screen 215. The user touches the character input screen 215, making it possible to input the name of the user using predetermined characters or symbols.

And, the user may set predetermined images to be displayed together with the user name by selecting the image selecting unit 211c. When the user touches the image selecting unit 211c, the controller displays an image list that is previously stored in the memory or is stored in the external memory device connected to the communication port 22 on the input device 21. Alternately, the controller may move and store the images stored in the external memory device into the memory, and then may display the image list moved and stored in the memory. The user may select his or her desired images of the displayed image list to set them as the corresponding user's images.

And, if the user touches a storage button 211d provided on the lower side of the user set screen 211, the input contents are stored in the memory.

Meanwhile, a handwriting recognition scheme that a user's touches are recognized as they are and are stored may be used on the character input screen 215, in addition to an input scheme of a keyboard scheme that a user selects characters and symbols, etc. Also, the keyboard scheme and the handwriting recognition scheme may be selectively provided. In the present invention, the character input screen 215 will be described in the manner that the characters or the symbols, etc. are input similarly to a general computer keyboard by way of example.

The respective user information stored in the memory as described above are displayed on the display unit 53. The detailed description thereof will be described later. Further, in the present embodiment, the user of the first district will be described as a first user, the user of the second district will be described as a second user, and the user of the third district will be described as a third user by way of example.

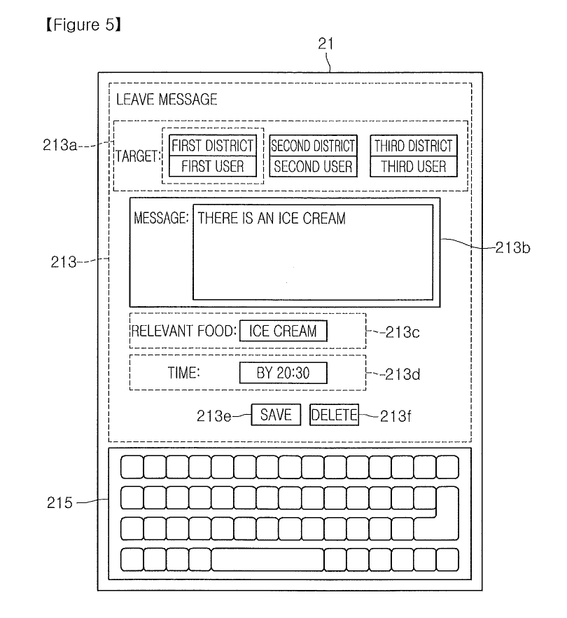

FIG. 5 is a diagram showing a screen on which a message is left to the user of the personal chamber of FIG. 1.

Referring to FIG. 5, the user who uses the refrigerator 1 can leave a predetermined message to the user of the personal chamber 13.

When the user selects a predetermined menu of the input device 21, the controller displays a message input screen 213 that the user can leave a message to the user of the personal chamber 13 on the input device 21. And, the character input screen 215 may be displayed on the lower side of the message input screen 213. The message input screen 213 may be switched right after the user information is stored in the user set screen 211, to be displayed on the input device 21.

The message input screen 213 includes an target selecting unit 213a that selects an target to whom the user leaves a message, a message input unit 213b that inputs the message contents, a food selecting unit 213c that selects food related to the message, and a time set unit 213d that sets the display time of the message.

The controller displays the users who use the personal chamber 13 sequentially on the target selecting unit 213a based on the information input on the user set screen 211.

In the present embodiment, the first user, the second user, and the third user are displayed sequentially.

If the user selects the target to whom he or she leaves a message in the target selecting unit 213a, the message input unit 213b is activated and the user can leave a message configured of characters or symbols, etc. using the character input screen 215. The message that the user inputs using the character input screen 215 is stored in the memory.

And, when inputting the message, the user may select the food related to the contents of the message to allow the position where the relevant food is stored to be displayed together with the message. More specifically, the sort and the positions of the foods stored in the refrigerator 1 are stored in the memory by the RFID readers 31, 32, and 33. If the user selects the food selecting unit 213c, the controller may control the food list stored in the memory to be read and thus to be displayed on the input device 21, and the user may select the food related to the message, of the list. The selected information as described above is stored together with the message to be used when displaying the message.

Further, the user may set the time when the message is to be displayed on the display unit 53. If the user touches the time set unit 213d, the time when the message is to be displayed or the display is terminated can be set. For example, when wishing that the message is to be displayed by 7:00 PM, the user may set ‘7:00 PM’ in the time set unit 213d.

If a save button 213e is input after the message and the information related thereto are input as described above, the contents input on the message input screen 213 are stored in the memory. A delete button 213f that can delete the contents stored in the memory may also be provided, in addition to the save button 213e.

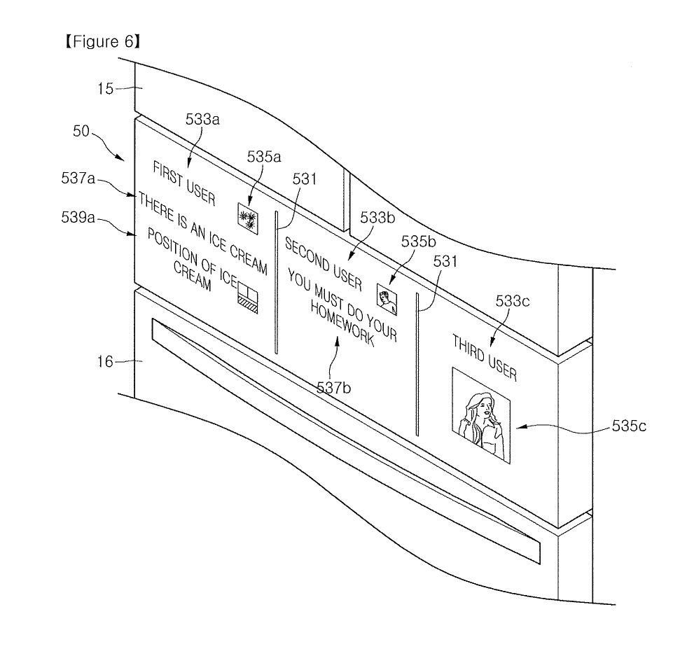

FIG. 6 is a diagram showing the display unit of the personal chamber drawer of FIG. 1.

Referring to FIG. 6, the controller displays the information input on the user set screen 211 and the message input screen 213 on the display unit 53, together with the partition information of the container 55.

More specifically, partition bars 531 are displayed on the spots corresponding to the positions of the partitions 57 in the display unit 53. The partition bar 531 may be formed in a rod shape that is vertically extended so that the user can conceptually recognize that the internal space of the container 55 is partitioned.

More specifically, the controller can recognize the positions and the number of the partitions 57 by the contact between the metal plates 575 and the electrodes 557. And, since the positions and the number of the guide grooves 553 are stored in the memory, the controller can display the partition bars 531 on the display unit 53 to correspond to the positions of the partitions 57 by combining the positions and the number of the partitions 57 and the positions and the number of the guide grooves 553. Therefore, the user recognizes the partition bars 531 displayed on the display unit 53, thereby making it possible to recognize how the container 55 is partitioned.

In the present embodiment, two partitions 57 are provided by way of example so that two partition bars 531 are displayed on the position where the respective partitions are provided. Upon seeing that the display unit 53 is partitioned into three districts, the user can recognize that the container 55 has three spaces. The user also can infer the width of each space from the positions of the partition bars 531.

The controller displays the user information corresponding to each district and the message left to the user on the display unit 53. More specifically, one display region partitioned by the partition bar 531 includes a user name display unit 533 that displays a user name, an image display unit 535 that displays an set image to the corresponding user, a message display unit 537 that displays the left message to the corresponding user, and a food display unit 539 that displays the food information related to the corresponding message.

At this time, the information of each user and the messages left to the users are displayed on the display regions corresponding to the front surface of the spaces that the users use. In other words, the information of the first user and the message left to the first user are displayed on the leftmost region of the space partitioned by the partition bar 531.

The image display unit 535, the message display unit 537, and the food display unit 539 may also be selectively displayed. In other words, if there are contents stored in the memory, they may be displayed and if there are not contents stored in the memory, they may not be displayed. And, the size of the display unit is determined according to the display of other display units.

More specifically, describing the case of the display region corresponding to the first district by way of example, the name 533a of the first user and the image 535a corresponding to the first user are displayed on the upper side of the district partitioned by the partition bar 531. And, the message 537a left to the first user is displayed under the name 533a and the image 535a of the first user and the food name related to the message 537a and the position 539a of the food are displayed under the message 537a. The position of the food 539a may be displayed on a refrigerator form that is shaped so that the respective storage chambers such as the refrigerating chamber 11, the freezing chamber 12, the personal chamber 13, etc. can be distinguishably represented.

When there is no food information related to the message, only the name 533b and the image 535b of the user and the message 537b may be displayed, as displayed on the display region corresponding to the second district in the drawing, and when there is no message, either, only the name 533c and the image 535c of the user may be displayed, as displayed on the display region corresponding to the third district in the drawing.

The controller controls the message display unit 537 and the food display unit 539 to be displayed only during the time or by the time that the user inputs on the message input screen 213 and then to be disappeared. In this case, the screen displayed on the display unit 53 may be changed into the screen corresponding to the third district from the screen corresponding to the first district or the second district.

With the refrigerator according to the first embodiment of the present invention as described above, the container 55 is partitioned by the partitions 57, making it possible to provide personal receiving space for each of the members who use the refrigerator 1.

At this time, the positions where the partitions 57 are installed are automatically displayed on the drawer 50 so that the user can conveniently recognize where his or her personal space is positioned, making it possible to feel satisfaction.

Moreover, the plurality of guide grooves 553 are provided, making it possible to easily change the area of the personal receiving space.

Further, the display region that displays his or her personal space can be decorated with his or her style images, etc., making it possible to maximize the satisfaction.

In addition, the communication between the users who use the refrigerator 1 can be made using the input device 21 and the display unit 53.

Moreover, in the communication, the relevant food information is also provided using the RFID technique, making it possible to improve use convenience.

Hereinafter, a refrigerator according to a second embodiment of the present invention will be described with reference to the drawing. However, compared with the first embodiment, the second embodiment has differences in view of the structure of the personal chamber so that it will be described centering on the differences and the same portions will be indicated using the same description and the reference numerals of the first embodiment.

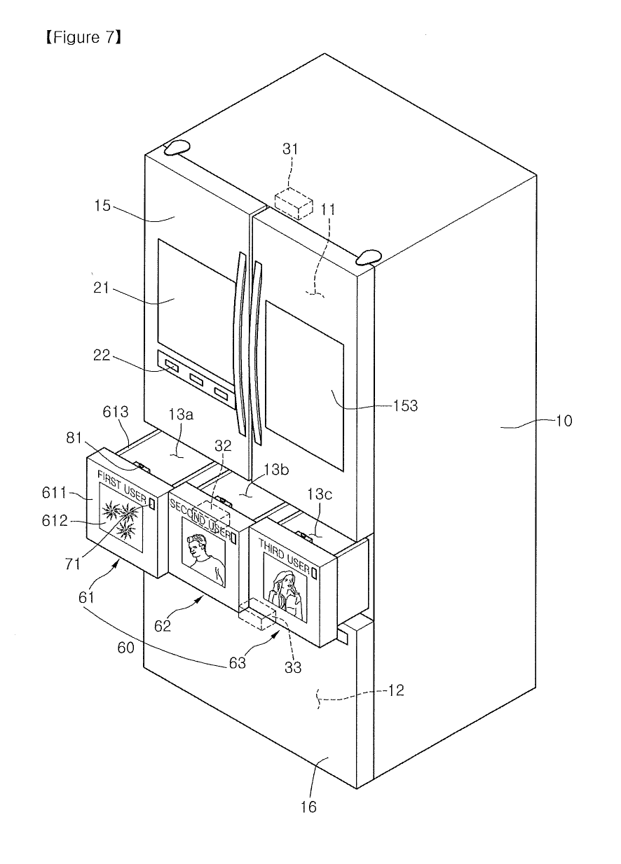

FIG. 7 is a diagram showing an external appearance of a refrigerator according to a second embodiment of the present invention.

Referring to FIG. 7, the refrigerator according to the second embodiment of the present invention is independently provided with a plurality of personal chambers. More specifically, the space between the refrigerating chamber 11 and the freezing chamber 12 is divided into several independent spaces by a predetermined barrier, wherein respective drawers 60 are provided in the independent spaces.

In the present embodiment, the personal chamber will be partitioned into three independent spaces 13a, 13b, and 13c by way of example. In other words, a first drawer 61 is provided in the first personal chamber 13a, a second drawer 62 is provided in the second personal chamber 13b, and a third drawer 63 is provided in the third personal chamber 13c.

At this time, the first drawer 61 includes a personal chamber door 611 that opens and closes the entrance of the personal chamber, a first display unit 612 that is mounted to the first personal chamber door 611, and a first container 613 that is coupled to the rear surface of the first personal chamber door 611 to store food. Partitions (not shown) and guide grooves (not shown) may also be provided in the first container 613 in the same manner as the first embodiment. Further, the first display unit 612 may display the information of the user who uses the partitioned spaces in the first container 613 or the message left to the user. The second drawer 62 and the third drawer 63 may also be constituted in the same manner as the first drawer 61.

With the refrigerator according to the second embodiment of the present invention, the first personal chamber 13a, the second personal chamber 13b, and the third personal chamber 13c are spaces independent from each other, having an advantage that the controller can differently control the temperatures of the respective personal chambers.

Meanwhile, a locking function may further be provided in the drawer 60. In other words, the respective drawers 61, 62, and 63 may be provided to be used only by the users of the respective personal chambers 13a, 13b, and 13c. More specifically, the first personal chamber door 611 may further be provided with a recognition device 71 such as a fingerprint recognition device, a voice recognition device, etc. that recognizes the user, and a fixing device 81 that fixes the first drawer 61 to the main body 10 or the inner case of the first personal chamber 13a. The fixing device 81 is operated to maintain a state where the first drawer 61 is closed according to the command of the controller.

For example, the controller may constitute the user set screen 211 to receive the user identification information. In this case, the user identification information may be stored in the memory, together with the names and images, etc. of the user.

The user identification information may be set in various methods, such as a fingerprint, recognition, an iris, a password, etc.

And, the controller may control the fixing device 81 to allow the first drawer 61 to be opened only when the information input through the recognition device 71 is consistent with the user identification information stored in the memory.

The second drawer 62 and the third drawer 63 may also be constituted in the same manner as the first drawer 61.

The scope of the present invention is not limited to the embodiment set forth herein, but modification, adding and removing can be made in the present invention without departing from the spirit and scope of the invention.

With the refrigerator according to the embodiment of the present invention, the personal receiving space of each of the members who use the refrigerator is provided so that the satisfaction for the product is improved, having industrial applicability.

1. A refrigerator comprising:
a main body that has a refrigerating chamber and a freezing chamber that store foods at low temperature;
a refrigerating chamber door and a freezing chamber door that selectively open and close the refrigerating chamber and the freezing chamber;
a personal chamber that is provided between the refrigerating chamber and the freezing chamber;
a drawer that is slidably and drawably provided in the personal chamber;
at least one partition that partitions a receiving space inside the drawer; and a display unit that is provided on the front surface of the drawer to display partition bars on positions corresponding to positions of the partitions.

2. The refrigerator according to claim 1, wherein a plurality of coupling parts to which the partitions are coupled are horizontally provided in the drawer.

3. The refrigerator according to claim 2, wherein electrodes that sense the contact of the partitions are provided in the coupling parts and metal plates are provided in the partitions, the metal plates being provided on positions corresponding to the electrodes.

4. The refrigerator according to claim 1, wherein a cover made of transparent material is attached to the front surface of the drawer.

5. The refrigerator according to claim 1, further comprising:
an input device that receives user information who uses each space partitioned by the partitions or a message left to the user who uses the each space; and
a memory that stores the user information or the message input by the input device,
wherein the display unit displays the user information or the message stored in the memory on a display region partitioned by the partition bars.

6. The refrigerator according to claim 5, wherein the user information or the message for the user is displayed on the display region corresponding to a space for the user.

7. The refrigerator according to claim 5, wherein the input device is provided on any one of the refrigerating chamber door and the freezing chamber door.

8. The refrigerator according to claim 5, wherein the input device is provided in a touch screen scheme and the user information or the message is able to be selectively input in any one of a keyboard scheme and a handwriting recognition scheme.

9. The refrigerator according to claim 5, wherein the input device also receives an image corresponding to the user when the user information is input.

10. The refrigerator according to claim 5, wherein the input device also receives a display time of the message when the message is input and the display unit selectively displays the message according to the display time.

11. The refrigerator according to claim 5, further comprising:
at least one RFID reader that identifies food information,
wherein the input device displays a food list that is recognized through the RFID reader so that the user is able to select the relevant food when inputting the message.

12. The refrigerator according to claim 11, wherein the RFID readers are provided in the refrigerating chamber, the freezing chamber, and the personal chamber, respectively.

13. The refrigerator according to claim 11, wherein the food information selected by the user is stored in the memory and the display unit displays the food information stored in the memory together with the message.

14. A refrigerator comprising:
a main body that has a refrigerating chamber and a freezing chamber that store foods at low temperature;
a refrigerating chamber door and a freezing chamber door that selectively open and close the refrigerating chamber and the freezing chamber;
a plurality of personal chambers that are provided between the refrigerating chamber and the freezing chamber;
drawers that are slidably and drawably provided in the respective personal chambers;
a display unit that is provided on a front surface of the respective drawers to display user information of the corresponding personal chamber; and
fixing devices that are provided in the drawers to selectively fix the drawers to the main body according to user who intends to open the drawers.

15. The refrigerator according to claim 14, wherein a recognition device that recognizes user identification information is further included.

16. The refrigerator according to claim 15, wherein the user identification information is at least one of a fingerprint and voice.
